(19) United States
(12) Patent Application Publication
(10) Pub. No.: US 2010/0314901 A1
(43) Pub. Date: Dec. 16, 2010

(54) Vehicle Cover

(76) Inventor: Winstun Glasgo, (US)

Correspondence Address: HARSHAW RESEARCH, INC., 210 W. TECUMSEH STREET, OTTAWA, KS, 66067, US

(21) Appl. No.: 12/484,346

(22) Filed: Jun. 15, 2009

(51) Int. Cl. B62D 25/06; H01R 24/00; H01L 31/042

(52) U.S. Cl. 296/136.07; 439/660; 136/244

(57) ABSTRACT

A vehicle cover includes an inner layer of flexible material configured to removably cover at least a portion of a vehicle. The vehicle cover includes a waterproof outer layer of flexible material operatively coupled to the inner layer to protect the inner layer from external environment elements. At least one solar cell is operatively coupled to at least one of the inner layer and the outer layer. The vehicle cover includes a first plug separated from the solar cell. Wiring is in electrical communication with the solar cell and the first plug and travels between the inner and outer layers.

### BACKGROUND OF THE INVENTION

This invention relates generally to automobile covers and, more particularly, to a vehicle cover having multiple solar cells for generating electricity for use by an electric powered vehicle or for transferring collected solar energy to an electrical storage device or even an active electric grid.

Electrically powered automobiles are increasing in popularity as the urgency to pursue cleaner energy solutions rises. While the rationale that electric cars run “cleaner” than internal combustion engines is true, the source of the electricity for the electric powered cars is generated in high pollution coal-fired plants. Therefore, there is a need for a “clean” source of electricity for use with a “clean” electrically powered vehicle.

While wind powered turbines, water turbines, and even most solar collectors may be clean methods of generating electricity, they are in most cases not feasible for use by electrically powered cars due to their relatively distant proximity when needed.

Therefore, it would be desirable to have a vehicle cover having multiple solar cells for generating electricity when in use covering a car. Further, it would be desirable to have a vehicle cover having a plurality of plugs such that collected solar energy may be transferred to the electric vehicle it is covering. In addition, it would be desirable to have a vehicle cover that may interface with a parking meter or other receptacle configured to receive collected solar energy and, optionally, to provide monetary value in exchange for collected energy.

### SUMMARY OF THE INVENTION

Therefore, a vehicle cover according to the present invention includes an inner layer of flexible material configured to removably cover at least a portion of a vehicle. The vehicle cover includes a waterproof outer layer of flexible material operatively coupled to the inner layer to protect the inner layer from external environment elements. At least one solar cell is operatively coupled to at least one of the inner layer and the outer layer. The vehicle cover includes a first plug separated from the solar cell. Wiring is in electrical communication with the solar cell and the first plug and travels between the inner and outer layers.

Therefore, a general object of this invention is to provide a vehicle cover for a vehicle that protects the vehicle from negative effects of weather elements.

Another object of this invention is to provide a vehicle cover, as aforesaid, that may be folded and stored such as in a vehicle trunk.

Still another object of this invention is to provide a vehicle cover, as aforesaid, that includes a plurality of solar cells for collecting solar rays from multiple angles.

Yet another object of this invention is to provide a vehicle cover, as aforesaid, having at least one plug for interfacing with an electric power receptacle of a vehicle.

A further object of this invention is to provide a vehicle cover, as aforesaid, that may be operatively connected with an electric power receptacle of a collection device not associated with a vehicle.

Other objects and advantages of the present invention will become apparent from the following description taken in connection with the accompanying drawings, wherein is set forth by way of illustration and example, embodiments of this invention.

### BRIEF DESCRIPTION OF THE DRAWINGS

FIG. 1 is a perspective view of a vehicle cover according to a preferred embodiment of the invention removed from a vehicle;

FIG. 2 is a perspective view of the vehicle cover as in FIG. 1 covering a vehicle;

FIG. 3 is another perspective view of the vehicle cover as in FIG. 2 with inner and outer layers removed;

FIG. 4 is an isolated view on an enlarged scale of a plug taken from FIG. 2;

FIG. 5 is a top view of the vehicle cover as in FIG. 2;

FIG. 6 is a sectional view taken along line 6-6 of FIG. 5;

FIG. 7 is a fragmentary view of multiple vehicle covers being connected to respective external power receptacles;

FIG. 8 is an isolated view on an enlarged scale taken from FIG. 7;

FIG. 9 is a sectional view taken along line 9-9 of FIG. 8; and

FIG. 10 is a block diagram of the electric components of the present invention.

### DESCRIPTION OF THE PREFERRED EMBODIMENT

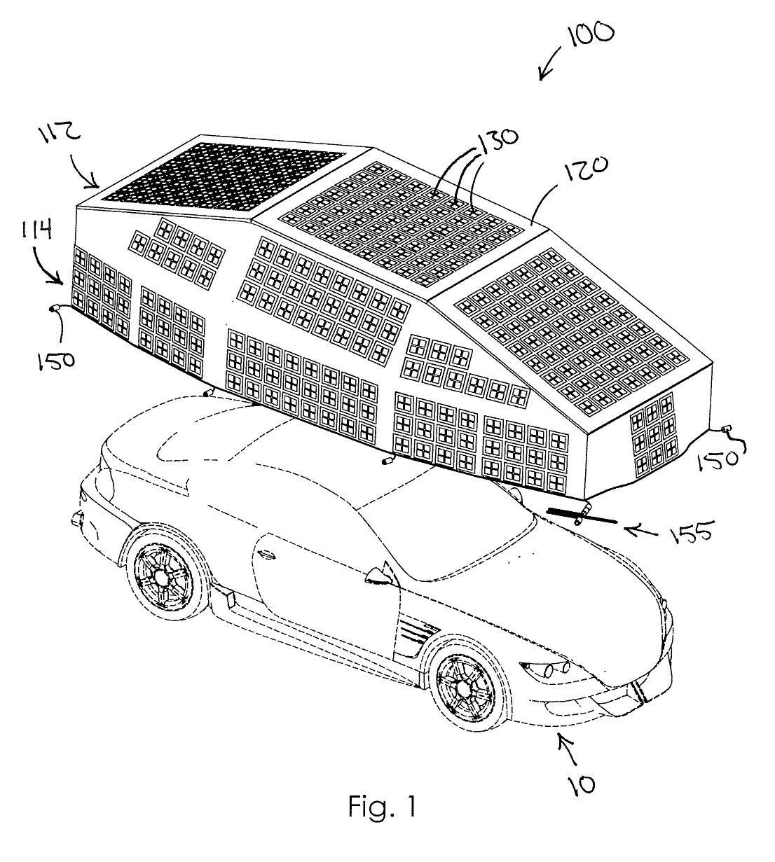

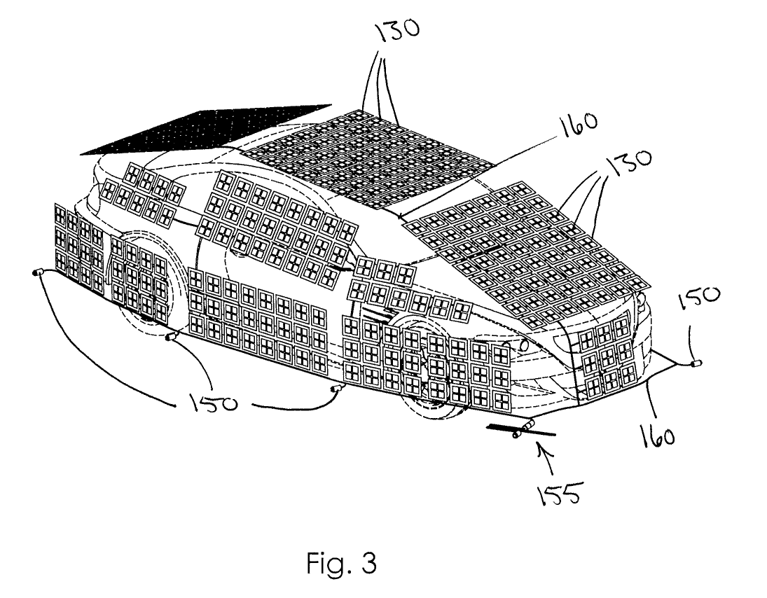

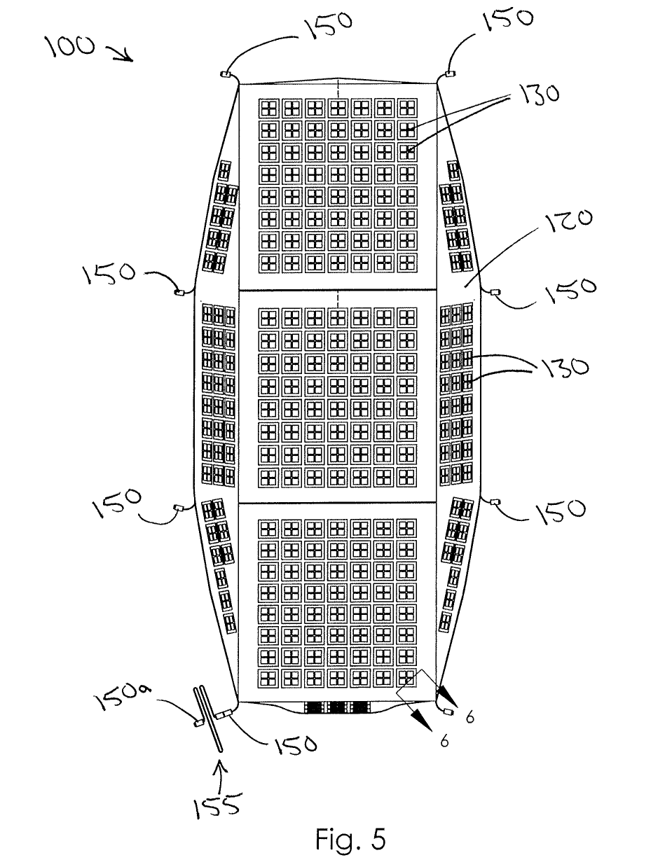

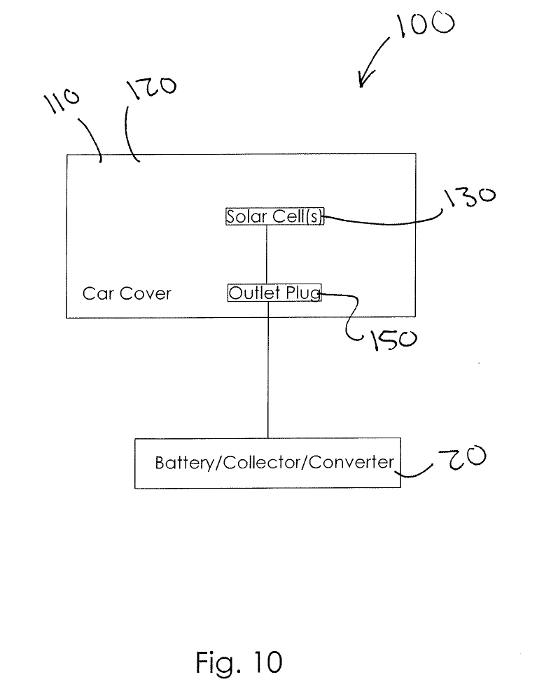

A vehicle cover 100 and associated systems and methods of use will now be described in detail with reference to FIG. 1 through FIG. 10 of the accompanying drawings. More particularly, a vehicle cover 100 of one embodiment includes inner and outer layers of flexible materials 110, 120, at least one solar cell 130, and at least one plug 150.

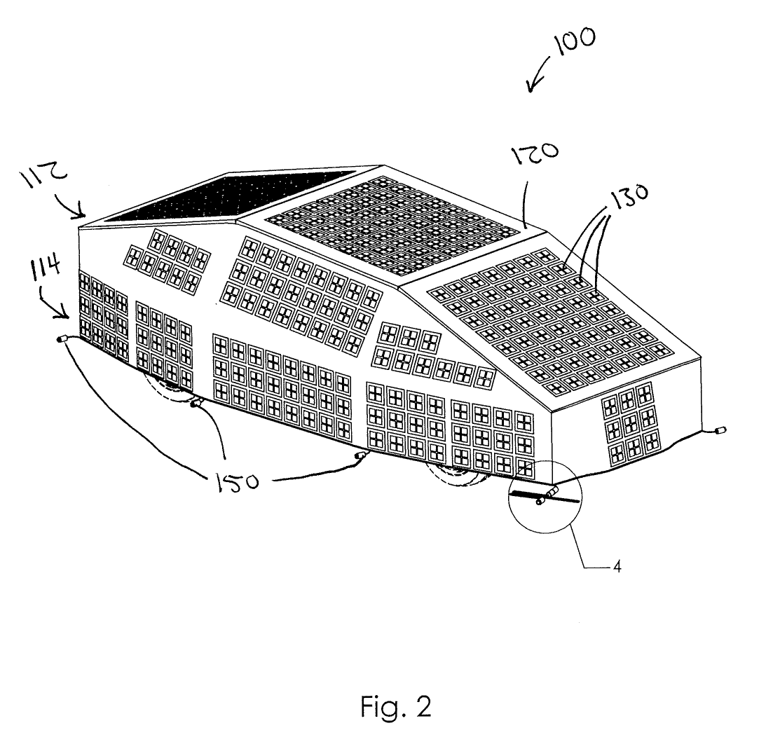

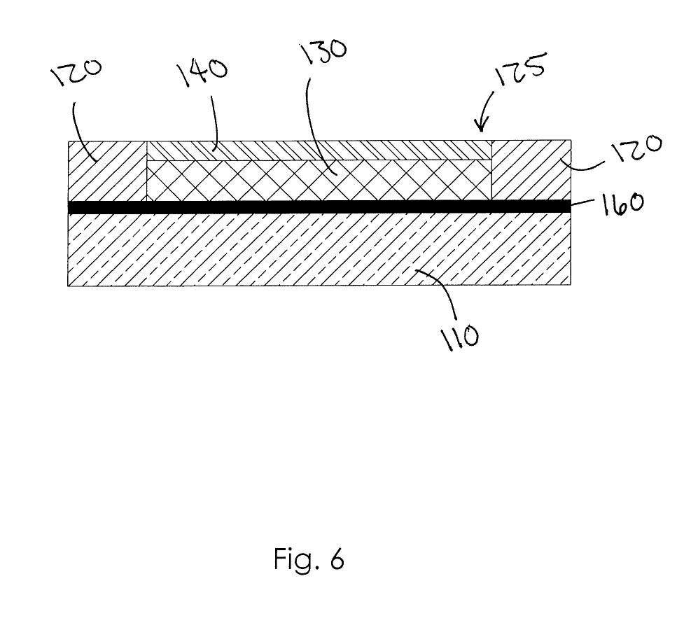

As shown in FIG. 6, the outer layer of flexible material 120 is operatively coupled to the inner layer of flexible material 110. The outer layer 120 may be waterproof and is coupled to the inner layer 110 to protect the inner layer 110 from external environment elements (e.g., rain, sunlight, hail, etc.). The inner layer 110 is configured to removably cover at least a portion of a vehicle 10 (e.g., an automobile, boat, etc.). The inner layer 110 may be soft and/or cushioned to protect the vehicle 10 which it covers from being scratched or otherwise damaged by the inner layer 110. In some embodiments, as shown in FIGS. 1 and 2, the inner layer 110 may be configured to cover all or substantially all of the vehicle 10 and may be tailored such that the inner layer 110 matches the form of the vehicle 10. An upper area 112 of the inner and outer layers 110, 120 may be above a lower area 114 of the inner and outer layers 110, 120 when the inner layer 110 covers the vehicle 10 (or the portion of the vehicle 10 which it is configured to cover), as also shown in FIGS. 1 and 2.

The solar cells 130 are operatively coupled to the inner layer 110 and/or the outer layer 120 so that the solar cells 130 may produce electricity from sunlight while the inner layer 110 covers the vehicle 10 (or the portion of the vehicle 10 which it is configured to cover). In some embodiments, various arrays of solar cells 130 are used (FIGS. 1, 2, 3, and 5). Any type, number, and size of solar cells 130 may be used, as will be appreciated by one of ordinary skill in the art. The outer layer 120 may define at least one window 125, and the solar cell(s) 130 may be positioned inside the window(s) 125, as shown in FIG. 6. Further, the solar cell(s) 130 may be covered by at least one transparent shield 140 (FIG. 6) to protect the solar cell(s) 130 from external environment elements (e.g., rain, sunlight, hail, etc.). In some embodiments, the transparent shield(s) 140 are positioned inside the window(s) 125 above the solar cell(s) 130 such that the outer layer 120 and transparent shield(s) 140 are generally flush (FIG. 6).

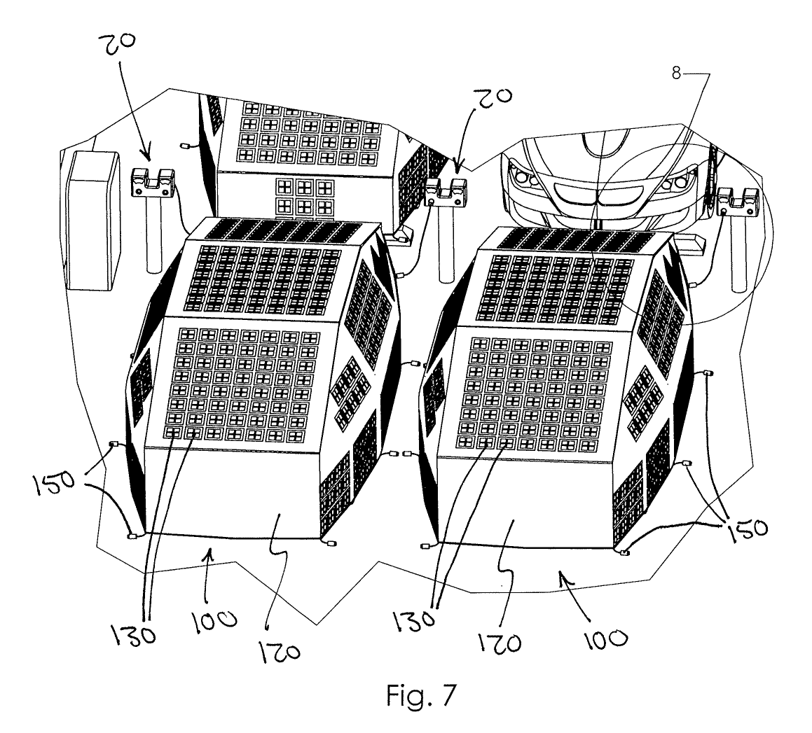

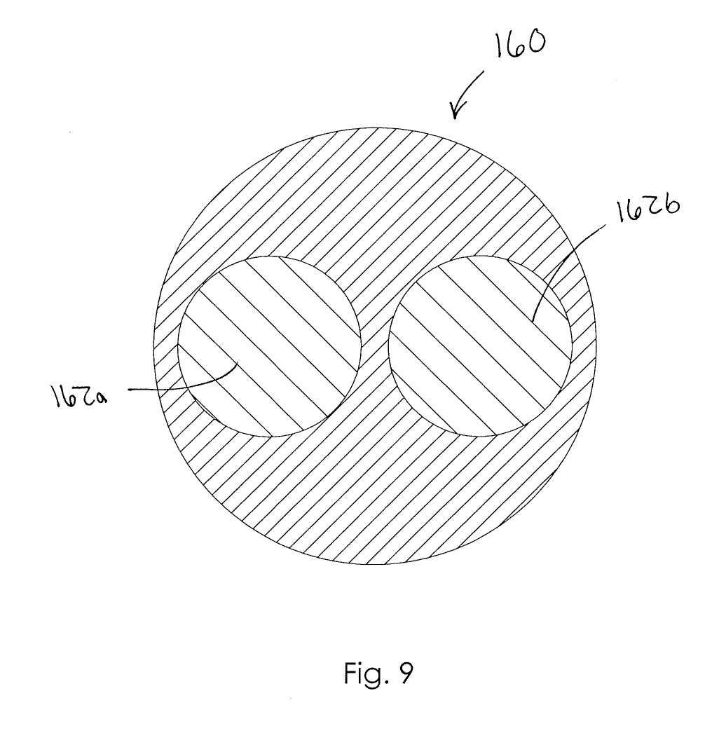

Though only one plug 150 separated from the solar cell(s) 130 may be included in some environments, it may be preferable for multiple plugs 150 separated from the solar cell(s) 130 to be included, as shown in FIG. 2. While embodiments with multiple plugs 150 are generally discussed herein, it should nevertheless be appreciated that a single plug 150 may be used instead. The plugs 150 may be configured complementary to a power receptacle of the vehicle 10 and/or an external power receptacle 20 for interacting therewith to output power generated by the solar cell(s) 130 (FIGS. 7, 8, and 10), and wiring 160 is in electrical communication with the solar cell(s) 130 and the plugs 150 to transport the electricity from the solar cell(s) 130 to the plugs 150. The wiring 160 may travel between the inner and outer layers 110, 120, as shown in FIG. 6, and may include positive and negative wires 162a, 162b (FIG. 9). As shown, for example, in FIG. 2, the plugs 150 may be adjacent the lower area 114 of the inner and outer layers 110, 120 to anchor the inner layer 110 in place covering the vehicle 10 (or the portion of the vehicle 10 which it is configured to cover).

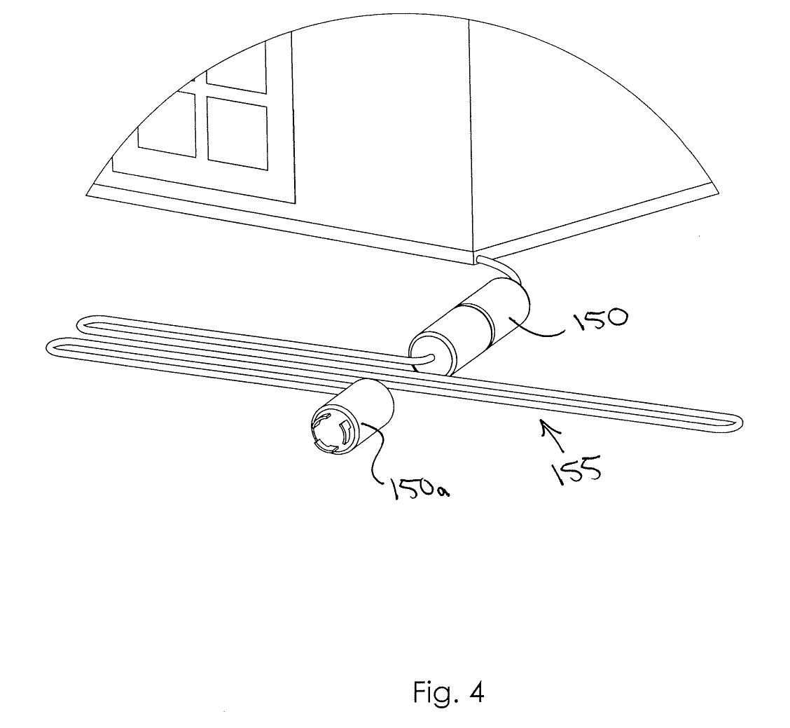

It should be realized that the plugs 150 may interact directly with the power receptacle of the vehicle 10 and the external power receptacle 20, or that a cable 155 with a plug 150a (FIG. 4) may connect the respective plugs 150 with the power receptacle of the vehicle 10 and the external power receptacle 20. If such a cable 155 is used, the cable 155 may be considered simply part of the wiring 160.

In use, the cover 100 may be positioned such that the inner layer of material 110 covers the vehicle 10 (or the desired portion of the vehicle 10) and the outer layer of material 120 protects the inner layer 110 (as well as the vehicle 10) from the external environment elements. The transparent shield(s) 140 may protect the solar cell(s) 130 from the external environment elements, as described above, and the plugs 150 may help maintain the cover 100 in place over the vehicle 10 by anchoring (i.e., weighing down) the cover 100 as described. The solar cell(s) 130 may produce electricity, as is appreciated in the art, and the wiring 160 may transfer the electricity that is generated to the plugs 150, one of which is plugged in to a power receptacle of the vehicle 10 or an external power receptacle 20 so the electricity may be used or stored.

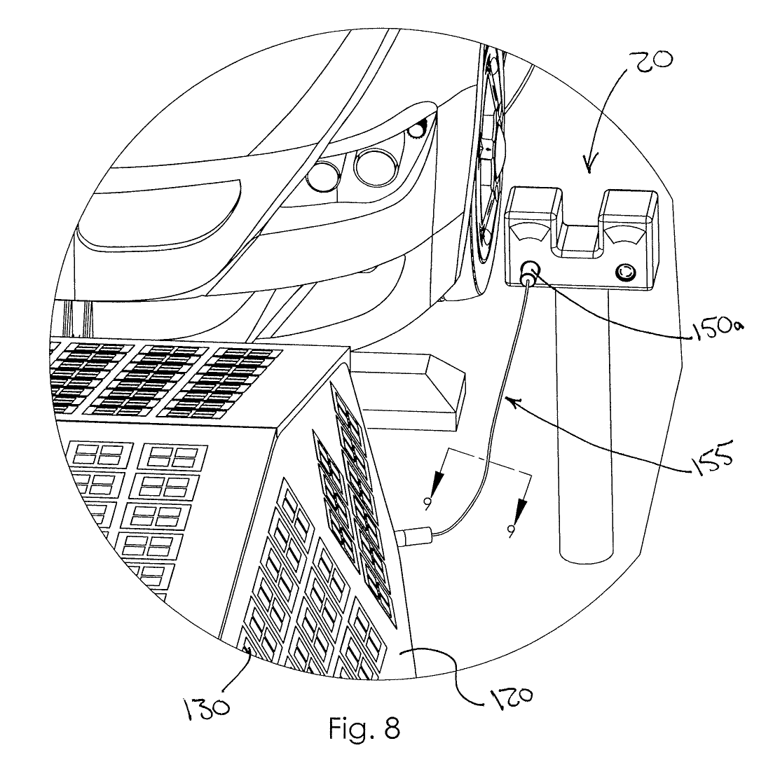

In some embodiments, the external power receptacle 20 receives and stores the generated electricity (or transfers the generated electricity for use) and meters the amount of electricity received. The owner of the cover 100 may then be compensated for the electricity received by the external power receptacle 20. For example, if the external power receptacle 20 is located in a parking lot (FIGS. 7 and 8), the cost of parking at that lot may be decreased by the amount of value associated with the electricity received by the external power receptacle 20. If the value of the electricity is greater than the cost of parking, a credit may be provided for future parking. The external power receptacle 20 may additionally provide electricity to vehicles 10, and the electricity received from the cover 100 may be transferred to another vehicle 10 at another linked external power receptacle 20 or may be stored until transferred to another vehicle 10.

It is understood that while certain forms of this invention have been illustrated and described, it is not limited thereto except insofar as such limitations are included in the following claims and allowable functional equivalents thereof.

1. A vehicle cover, comprising:
an inner layer of flexible material configured to removably cover at least a portion of a vehicle;
a waterproof outer layer of flexible material operatively coupled to said inner layer to protect said inner layer from external environment elements;
at least one solar cell operatively coupled to at least one of said inner layer and said outer layer;
a first plug separated from said solar cell; and
wiring in electrical communication with said solar cell and said first plug and traveling between said inner and outer layers.

2. The vehicle cover of claim 1, further comprising:
a second plug separated from said solar cell; and
wiring in electrical communication with said solar cell and said second plug and traveling between said inner and outer layers;
wherein said inner layer of material has an upper area and a lower area, said lower area being beneath said upper area when said inner layer covers said at least portion of said vehicle; and
wherein said first and second plugs are adjacent said lower area to anchor said inner layer in place covering said at least portion of said vehicle.

3. The vehicle cover of claim 2, wherein:
said outer layer defines a window; and
said solar cell is positioned inside said window.

4. The vehicle cover of claim 3, further comprising a transparent shield covering said solar cell to protect said solar cell from external environment elements.

5. The vehicle cover of claim 4, wherein said transparent shield is positioned inside said window.

6. The vehicle cover of claim 5, wherein said first and second plugs are configured complementary to at least one of a power receptacle of said vehicle and an external power receptacle for interacting therewith to output power generated by said solar cell.

7. The vehicle cover of claim 6, wherein said inner layer of material is configured to cover all or substantially all of said vehicle.

8. The vehicle cover of claim 7, wherein said vehicle is an automobile.

9. The vehicle cover of claim 1, wherein:
said outer layer defines a window; and
said solar cell is positioned inside said window.

10. The vehicle cover of claim 9, further comprising a transparent shield covering said solar cell to protect said solar cell from external environment elements.

11. The vehicle cover of claim 10, wherein said first plug is configured complementary to at least one of a power receptacle of said vehicle and an external power receptacle for interacting therewith to output power generated by said solar cell.

12. The vehicle cover of claim 1, wherein said first plug is configured complementary to at least one of a power receptacle of said vehicle and an external power receptacle for interacting therewith to output power generated by said solar cell.
